(19) United States
(12) Patent Application Publication
(10) Pub. No.: US 2001/0040793 A1
(43) Pub. Date: Nov. 15, 2001

(54) Electronic device and method of producing the same

(76) Inventor: Tetsuya Inaba, Nagano (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 09/772,985

(22) Filed: Jan. 31, 2001

(30) Foreign Application Priority Data
Feb. 1, 2000 (JP) P2000-028950

(51) Int. Cl. H05K 1/18; H05K 1/11

(52) U.S. Cl. 361/749; 361/767; 174/254

(57) ABSTRACT

An electronic device comprising plurality of chips mounted at a high density as in a multi-chip module and having a reduced area and a thinner shape, provided with a folded flexible board having flexibility, chips mounted on a surface of the flexible board, and an adhesive comprising an insulating material filled between facing surfaces of the folded board for sealing the chips and affixing the facing surfaces.

### BACKGROUND OF THE INVENTION

1. Field of the Invention

The present invention relates to an electronic device and a method of producing the same.

Further, the present invention relates to an electronic apparatus using such an electronic device and a method of producing the same.

2. Description of the Related Art

In recent years, along with digitization of electronic apparatuses and the faster signal processing speed, there has been strong demand for suppressing noise of electronic apparatuses and lighter, thinner, and smaller electronic apparatuses. Also, recent electronic apparatuses contain large numbers of electronic components. It is therefore also necessary to suppress signal delays between chips.

To meet the above demand, for example, the practice has been to arrange a plurality of chips close to each other on a board to package them at a high density and thereby suppress signal delay between chips.

As a technology for realizing the above high density packaging, specifically there is known a so-called multi-chip module (MCM) wherein a plurality of bare chips are mounted on a printed wiring board such as a flexible printed wiring board and handled as a single component which is then mounted on a base printed wiring board.

FIG. 1 is a sectional view of an example of the configuration of a multi-chip module.

In the multi-chip module shown in FIG. 1, a plurality of chips 102 are mounted at a high density on a module board 101 on which a wiring pattern is formed. Due to this, the signal delay between the chips 102 is reduced. Also, the module board 101 is provided with a plurality of connection lands on the surface where the chips 102 are not mounted. The lands are electrically connected to corresponding connection lands on the base board 105 via connection materials 106 such as solder bumps.

An area array arrangement is applied to the connection lands formed on the module board 101 and the base board 105 to strongly connect the module board 101 and the base board 105.

In the above multi-chip module, as a method of mounting the chips 102 on the module board 101, there are known, for example, a wire bonding method wherein pads on the chip 102 and lands on the module board are connected by connection members like metal wires, a TAB method wherein inner leads of a thin film comprising a material like Cu formed on a tape carrier and pads of a chip are bonded by inner lead bonding, and a flip-chip connection method wherein bumps made of gold etc. are formed on pads on a chip and then the chip is directly connected to a board at the surface on which active element is formed. By mounting a bare chip on a module board using these connection methods with no more than the chip size, high density packaging is attained.

In a multi-chip module wherein bare chips are planarly mounted for realizing high density packaging explained above, however, the area of the module board required for the packaging, for example, is approximately doubled in case that the number of chips to be mounted increases from two to four. Therefore, in the related art, the module board area has to be enlarged in accordance with the increase of the area and number of chips to be mounted. Enlarging the module board area is disadvantageous in that it becomes difficult to reduce the size (area) of the electronic apparatus in which the multi-chip module is used.

On the other hand, Japanese Unexamined Patent Publication (Kokai) No. 6-13727 discloses another method of mounting bare chips on a flexible board to make a single component to be mounted on a base board. This publication discloses a method for preventing mechanical and thermal stress acting upon the base board from directly being transferred to the chips by mounting the chips on a folded flexible board and mounting the flexible board on the base board.

However, the method disclosed in the above publication is for decreasing transfer of mechanical and thermal stress to chips by indirectly packaging the chips on the base board by using a flexible board and is not suitable to high density packaging of chips by making a module using a flexible board to be folded thinner.

### SUMMARY OF THE INVENTION

An object of the present invention is to provide an electronic device comprising a plurality of chips mounted at a high density on a printed wiring board, such as a multi-chip module, which is capable of reducing an area occupied by the device and being made thinner.

Another object of the present invention is to provide a method of production of an electronic device comprising a plurality of chips mounted at a high density on a board which is capable of reducing an area occupied by the device and making the device thinner.

Still another object of the present invention is to provide an electronic apparatus using the above electronic device.

According to a first aspect of the present invention, there is provided An electronic device comprising a flexible board having at least printed wirings and folded at least one; at least one chip mounted on an inner surface of the facing surfaces of the folded flexible board; and an adhesive made of an insulating material filled between the facing surfaces of the folded flexible board for sealing the chip and integratedly fixing the facing surfaces and the chip.

Preferably, the chip is mounted on flat regions of the flexible board.

Further preferably, the flexible board is alternatively folded to form at least three stacked layers to aligne the both fold ends.

Preferably, at least one chip is mounted on each surface of the facing surfaces of the folded flexible board and the adhesive is interposed between the chips.

Preferably, the flexible board is connected to a base board designed for mounting the flexible board and provided with connection lands for electrically connecting the chip to a circuit formed on the base board.

Preferably, the chip is mounted on the flexible board by flip-chip bonding.

Further preferably, the chip is mounted in bare chip on the flexible board.

According to a second aspect of the present invention, there is provided an electronic apparatus comprising an electronic device having a flexible board to be folded, at least one chip mounted on a surface of the flexible board, and an adhesive made of an insulating material filled between facing surfaces of the folded board to affix the facing surfaces each other and seal the chip and a base board on which the electronic device is to be mounted.

According to a third aspect of the present invention, there is provided a method of producing an electronic device comprising the steps of mounting at least one chip on a surface of a flexible board; coating an adhesive made of an insulating material on the flexible board; and folding the flexible board to bond with the adhesive the facing surfaces of the flexible board and seal the chip with the adhesive.

Preferably, the method of production of an electronic device of the present invention further comprising a step of coating the adhesive so as to cover the chip mounted on the flexible board.

Preferably, the method of production of an electronic device further comprising the steps of mounting first and second chips at regions facing each other when the flexible board is folded; coating the adhesive so as to cover one of the first and second chips; and folding the flexible board to be fixed each other and seal the first and second chips with the adhesive.

According to a fourth aspect of the present invention, there is provided a method of producing an electronic apparatus comprising the steps of mounting at least one chip on a surface of a flexible board having flexibility; coating an adhesive made of an insulating material on the flexible board; folding the flexible board to bond with the adhesive the facing surfaces of the flexible board and seal the chip with the adhesive; and mounting the folded flexible board on a base board.

In the present invention, a flexible board on which chips are mounted chips are folded and affixed by filling an adhesive between facing surfaces of the folded flexible board. The adhesive also seals the chips.

Namely, the flexible board on which the chips are mounted has a relatively large area when laid flat, but by folding the flexible board to stack the chips, the area occupied by the electronic device can be reduced. In other words, a higher density packaging of chips becomes possible corresponding to the amount of reduction of the area occupied by the electronic device.

Also, by filling the insulating adhesive between facing surfaces of the folded flexible board to affix the flexible board and seal the chips, the flexible board on which the chips are mounted does not need to be newly installed in a package etc. and the flexible board folded to have many layers can be made thinner.

### BRIEF DESCRIPTION OF THE DRAWINGS

These and other objects and features of the present invention will become clearer from the following description of the preferred embodiments given with reference to the attached drawings, in which:

FIG. 1 is a sectional view of an example of the configuration of a multi-chip module;

FIG. 2 is a sectional view of the configuration of a multi-chip module according to an embodiment of an electronic device of the present invention;

FIG. 3 is a sectional view for explaining a production process of the multi-chip module shown in FIG. 2;

FIG. 4 is a plan view of a flexible board shown in FIG. 2;

FIG. 5 is a sectional view for explaining a production process continued from FIG. 3;

FIG. 6 is a sectional view for explaining a production process continued from FIG. 5;

FIG. 7 is a sectional view for explaining a production process continued from FIG. 6;

FIG. 8 is a sectional view for explaining a production process continued from FIG. 7;

FIG. 9 is a sectional view for explaining a production process continued from FIG. 8;

FIG. 10 is a sectional view of an example of the configuration of a multi-chip module wherein flip-chip packaging is applied;

FIG. 11 is a view for explaining a procedure of a flip-chip packaging process;

FIG. 12 is a view for explaining a packaging process continued from FIG. 11;

FIG. 13 is a view for explaining a packaging process continued from FIG. 12;

FIG. 14 is a view for explaining a packaging process continued from FIG. 13; and

FIG. 15 is a view for explaining a packaging process continued from FIG. 14.

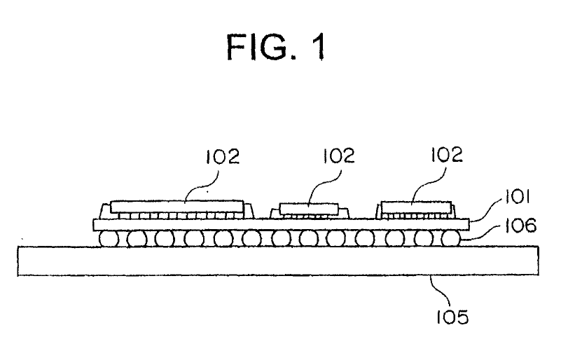

### DESCRIPTION OF THE PREFERRED EMBODIMENTS

Below, a detailed explanation of the preferred embodiment of the present invention will be given with reference to the accompanying drawings.

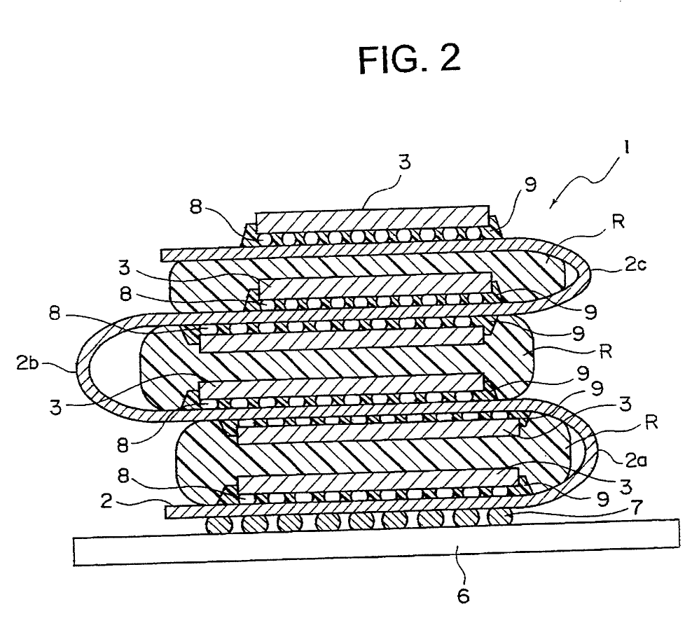

FIG. 2 is a sectional view of the configuration of a multi-chip module according to an embodiment of the present invention.

In FIG. 2, a multi-chip module 1 has a flexible board 2 being folded, a plurality of semiconductor chips 3 mounted on the surface of the flexible board, and an adhesive R filled between facing surfaces of the flexible board 2 being folded. The multi-chip module 1 is mounted on a rigid base board 6.

The base board 6 is a hard board having less flexibility on which a conductive wiring pattern is formed by a conductive material such as Cu. Specifically, it is a rigid printed wiring board formed of an insulating board obtained by impregnating a resin, such as an epoxy resin or imide resin, into a woven glass fabric as a backing material followed by curing and then printed with a conductive wiring pattern.

The flexible board 2 is a board formed of a base film having flexibility and an insulation property formed with a conductive wiring pattern and then covered with a cover film. For example, a base film made of polyester, polyamide, etc. is formed with a conductive wiring pattern by printing and then covered with a cover film.

The flexible board 2 has a thickness of, for example, about 30 μm.

The flexible board 2 is formed of a single board having a predetermined width folded at three positions to be bended 2a, 2b, and 2c along the longitudinal direction of the flexible board 2 to make four stacked layers.

The semiconductor chips 3 are mounted in a so-called bare chip at predetermined positions on the two sides of the flexible board 2 via bumps 8 made of a conductive material like gold and an anisotropic conductive material 9. As a result, the electronic circuits formed on the semiconductor chips 3 are electrically connected to the conductive wiring pattern formed on the flexible board 2.

Also, the plurality of semiconductor chips 3 are mounted on flat portions on the first to fourth layers of the flexible board 2 folded in four stacked layers as counted from the base board 6 side

Namely, semiconductor chips 3 are mounted on each of the facing surfaces of the first layer and the second layer. The semiconductor chips 3 mounted on the facing surfaces of the two layers face each other at their non-mounted surfaces.

Semiconductor chips 3 are also mounted on each of the facing surfaces of the second layer and the third layer of the flexible board 2. The semiconductor chips 3 mounted on the facing surfaces of the two layers face each other at their non-mounted surfaces.

Another semiconductor chip 3 is mounted only on the facing surface of the third layer among the facing surfaces of the third layer and the fourth layer of the flexible board 2. No semiconductor chip 3 is mounted on the facing surface of the fourth layer. Instead, a semiconductor chip 3 is mounted on the outer surface of the fourth layer of the flexible board 2.

On the surface of the first layer of the flexible board 2 facing the base board 6 are formed not shown connection lands to be connected to a plurality of bumps 7 made of a conductive material like gold. Namely, a plurality of connection lands are formed on one end of the flexible board 2.

The plurality of connection lands formed on one end of the flexible board 2 are arranged in a grid for strengthening connection between the flexible board 2 and the base board 6. Namely, the plurality of lands formed on one end of the flexible board 2 are arranged at regular intervals at a predetermined pitch lengthwise and crosswise.

The plurality of connection lands formed on one end of the flexible board 2 are connected to the connection lands formed correspondingly on the base board 6 in a grid via the bumps 7. As a result, the flexible board 2 and the base board 6 are electrically connected.

The adhesive R is made of insulating materials and is filled between the first and the second layers, the second and the third layers, and the third and the fourth layers of the flexible board 2 and cured.

The adhesive R is filled to cover the semiconductor chips 3 mounted on the facing surfaces of the first to fourth layers, fixes the relative positions of the four layers of the flexible board 2, and seals the facing semiconductor chips 3. Moreover, the adhesive R prevents the semiconductor chips 3 from contacting each other and electrically insulates them.

Next, a method of producing of the multi-chip module 1 configured as above and a method of mounting the same to the base board 7 will be explained.

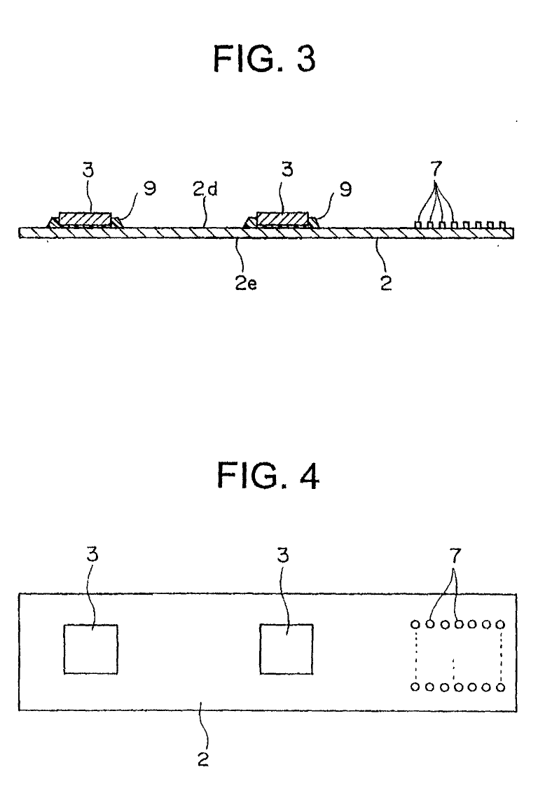

First, as shown in FIGS. 3 and 4, the semiconductor chips 3 are mounted at predetermined positions on one surface 2d of the flexible board 2.

The semiconductor chips 3 are mounted for example by flip-chip bonding. Note that FIG. 4 is a plan view of FIG. 3. Also, at one end of the one surface 2d of the flexible board 2 are formed a plurality of lands 7 in a grid.

Here, one example of a method of mounting the semiconductor chips 3 on the flexible board 2 will be explained with reference to FIGS. 10 to 15.

FIG. 10 is a sectional view of the configuration of the semiconductor chips 3 mounted on the flexible board 2 by flip-chip bonding.

In FIG. 10, connection lands 2f formed on the flexible board 2 are connected to the respective pads of the semiconductor chips 3 by bumps 8 and an anisotropic conductive material 9.

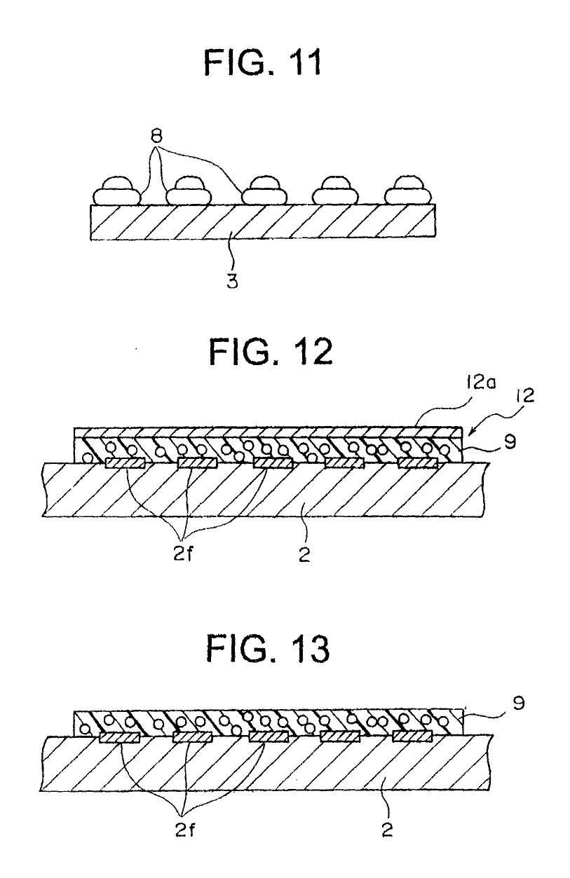

The configuration shown in FIG. 10 is formed, for example, by bonding the bumps 8 made of a conductive material like gold on the respective connection pads of the semiconductor chips 3 first as shown in FIG. 11.

Then, as shown in FIG. 12, an anisotropic conductive film 12 formed of a film of the anisotropic conductive material 9 held by a cover tape 12a is adhered on the surface of the flexible board 2.

The anisotropic conductive film 9 is made of a resin like epoxy resin in which are kneaded conductive particles like silver and becomes electrically conductive only in the direction to which pressure is applied and becomes insulating in the other directions.

As shown in FIG. 13, after adhering the anisotropic conductive material 9 in the anisotropic conductive film 12 on the surface of the flexible board 2, the cover tape 12a is removed.

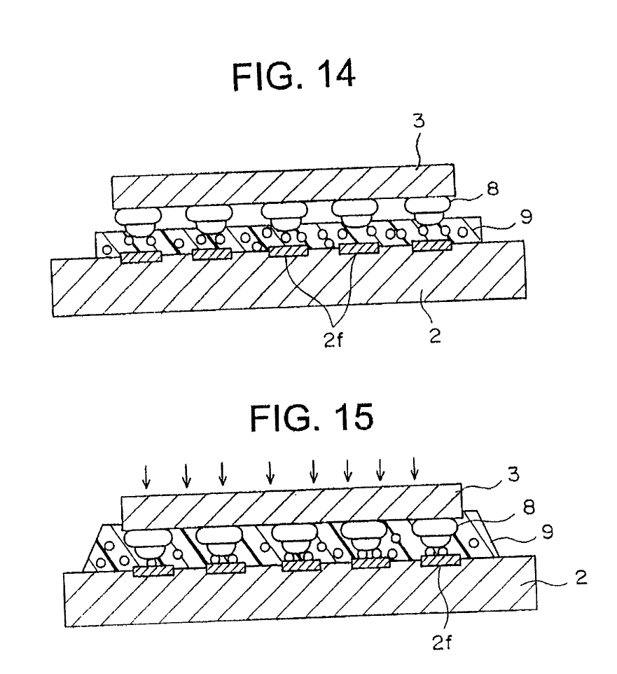

Then, as shown in FIG. 14, the semiconductor chips 3 formed with the bumps 8 are aligned with respect to the flexible board 2 on which the anisotropic conductive material 9 is adhered.

Next, as shown in FIG. 15, in the state with the semiconductor chips 3 aligned with respect to the flexible board 2, the semiconductor chips 3 and the flexible board 2 are pressed while heated by using a not shown pressing head.

At this time, the conditions of heating and pressing are, for example, a temperature of 160° C. to 190° C., a pressure of 20 to 60 kgf/cm², and a time of 20 to 30 seconds.

As a result of the heating and pressing, the conductive particles made of silver or other metal material contained in the anisotropic material 9 electrically connect the bumps 8 and the connection lands 2f formed on the flexible board 2.

Through the above procedure, the flip-chip bonding of the semiconductor chips 3 to the flexible board 2 is completed.

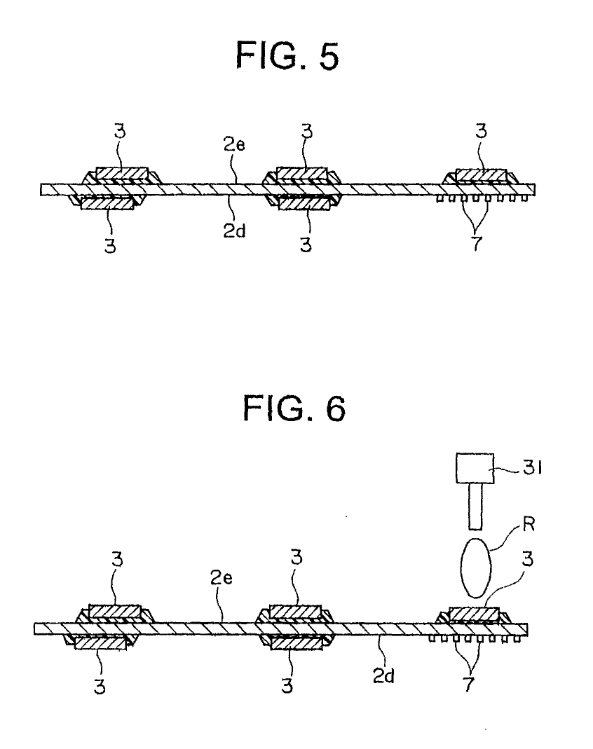

When the flip-chip bonding of the semiconductor chips 3 to the surface 2d of the flexible board 2 is completed, in the same way as explained with reference to FIG. 3, semiconductor chips 3 are mounted by flip-chip bonding on the other surface 2e of the flexible board 2 as shown in FIG. 5.

Also, the semiconductor chips 3 are mounted at approximately regular intervals along the longitudinal direction of the flexible board 2.

Next, as shown in FIG. 6, in a state with the semiconductor chips 3 mounted on the two sides of the flexible board 2, the insulating adhesive R is applied on the semiconductor chip 3 on the opposite surface 2e from the bumps 7 formed at one end of the flexible board 2.

At this time, an appropriate amount of the adhesive R is coated so as to cover the semiconductor chip 3 by using a dispenser 31.

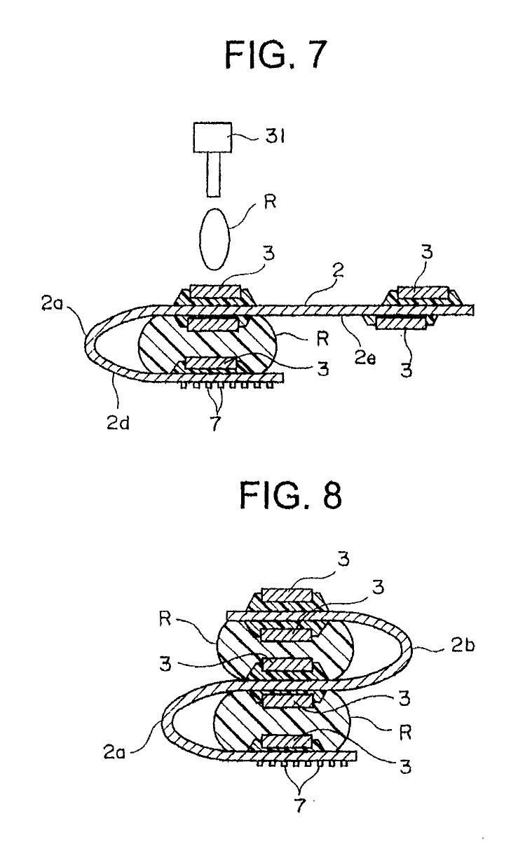

Next, as shown in FIG. 7, a predetermined position on the flexible board 2 is bent to a U-shape and folded so that the semiconductor chip 3 coated with the adhesive R faces the adjacent semiconductor chip 3.

When the flexible board 2 is folded, the two semiconductor chips 3 mounted on one surface 2e of the flexible board 2 face each other via the adhesive R. Namely, the semiconductor chip 3 not coated with the adhesive R becomes covered by the adhesive R due to the folding of the flexible board 2.

When the adhesive R is cured in the state with the flexible board 2 folded, the position to be bended 2a on the flexible board 2 is fixed to the bent state as shown in FIG. 7.

Next, the adhesive R is coated on the semiconductor chip 3 mounted on the other surface 2d of the flexible board 2 positioned over the two semiconductor chips 3 in the facing state mounted on the flexible board 2 in the state bent to a U-shape.

In the same way as above, an appropriate amount is coated to cover the semiconductor chips 3.

Then, in the state with the adhesive R coated on the semiconductor chip 3 mounted on the other surface 2d of the flexible board 2, the flexible board 2 is bent to an S-shape, so that the semiconductor chip 3 coated with the adhesive R mounted on the other surface 2d of the flexible board 2 faces a semiconductor chip not coated with the adhesive R via the adhesive R.

The semiconductor chip 3 not coated with the adhesive R mounted on the other surface 2d of the flexible board 2 is covered with the adhesive R due to the folding of the flexible board 2 by bending at the position to be bended 2b thereon.

Curing of the adhesive R results in fixing the flexible board 2 in a state folded in an S-shape.

As a result of folding the flexible board 2 to an S-shaped, a multi-chip module wherein the flexible board 2 becomes a three-layer structure is obtained where the connection lands 7 are arranged on the outer surface of the lowest layer, semiconductor chips 3 are arranged in a facing state on the facing surfaces of the lowest layer and the second layer, semiconductor chips 3 are arranged in a facing state on the facing surfaces of the second layer and the uppermost layer, and a semiconductor chip 3 is arranged on the outer surface of the uppermost layer.

Note that when configuring a multi-chip module having the four-layer structure as shown in FIG. 2, the positions for mounting the semiconductor chips 3 on the flexible board 2 have to be appropriately changed and the number of the positions to be bended on the flexible board 2 have to be changed to three, but the basic method of production is similar.

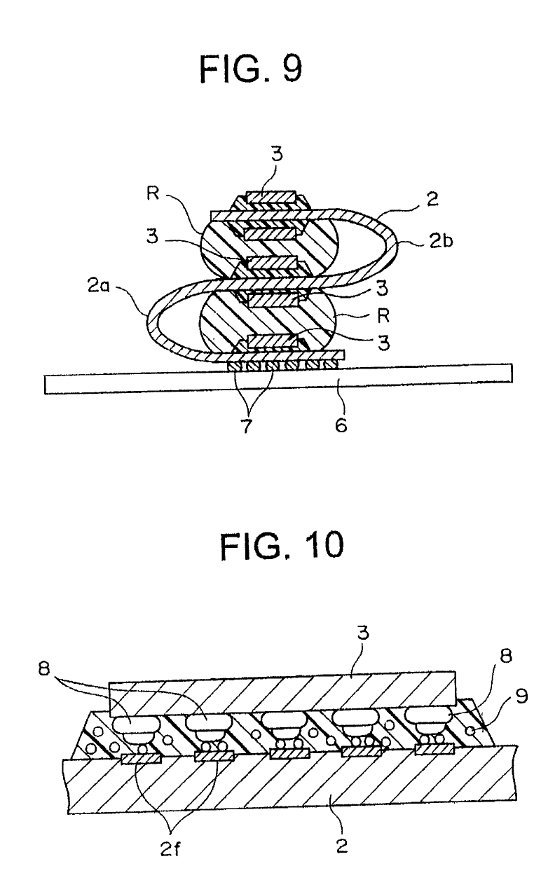

Next, as shown in FIG. 9, the multi-chip module completed after the above procedure is mounted on the base board 6.

The mounting to the base board 6 is carried out, for example, by coating a connection material such as solder paste on connection lands formed on predetermined positions of the base board 6 and mounting the connection lands 7 on the flexible board 2 at the positions to which the connection material is coated.

As explained above, according to the present embodiment, since the plurality of semiconductor chips 3 are arranged via the flexible board 2, the signal delay between the semiconductor chips 3 can be made short and a higher speed and higher performance can be attained in the overall system wherein the multi-chip module is applied.

Furthermore, according to the present embodiment, since the high density packaging is attained by spatially stacking the semiconductor chips 3 by folding the flexible board 2, limited mounting space can be utilized to the fullest.

Also, according to the present invention, even when an area (length) of the flexible board 2 increases for handling an increase of an area and number of the semiconductor chips 3, the final area occupied by the flexible board 2 is not increased because the flexible board 2 can be folded.

Furthermore, even if the area and number of the semiconductor chips 3 increase, an increase of the area of the flexible board 2 can be suppressed and as a result an area for mounting on the base board 6 can be also suppressed.

Also, according to the present embodiment, since an insulating adhesive R is filled and fixes the flexible board 2 being folded and since the semiconductor chips 3 are covered with the adhesive R and protected thereby, it is not necessary to additionally cover the flexible board 2 being folded with a package and the production process of the multi-chip module can be simplified.

Namely, in the present embodiment, since the adhesive R functions both to fix the flexible board 2 being folded and to seal the semiconductor chips 3 being mounted, the configuration of the multi-chip module can be simplified and the reliability can be improved. Moreover, since the flexible board 2 is folded and bonded with adhesive, an increase of the thickness of the multi-chip module 1 can be minimized.

Also, according to the present embodiment, in the case where the number of chips in the multi-chip module is changed, rearrangement in the multi-chip module is possible, thus it is not necessary to change the layout of the chips on the base board 6. Also, at the time of the change, the change can be easily handled by changing the number of the layers of the flexible board 2, changing the positions to be bended, etc.

The present invention is not limited to the above embodiment.

In the above embodiment, the number of the positions to be bended on the flexible board 2 was made to be 2 or 3, but the number of the positions to be bended is not specifically limited and may be larger to make more layers.

Also, a case was explained where a single semiconductor chip 3 is provided on the front surface and back surface of the respective layers of the flexible board 2 after folding, but more semiconductor chips 3 may be provided and components other than the semiconductor chips 3 can be mounted.

According to the present invention, in an electronic device wherein a plurality of chips are packaged on a board at a high density, it is possible to reduce the area occupied by the device and realize a high density packaging while suppressing an increase of the area occupied by the device.

Also, according to the present invention, the insulating adhesive fixes the folded flexible board and seals the chips mounted on the flexible board, so the production process can be simplified. Furthermore, it is not necessary to newly provide a package for sealing the chips, so the configuration can be simplified and the reliability can be improved.

Note that the embodiments explained above were described to facilitate the understanding of the present invention and not to limit the present invention. Accordingly, elements disclosed in the above embodiments include all design modifications and equivalents belonging to the technical field of the present invention.

What is claimed is:

1. An electronic device comprising:
a flexible board having at least printed wirings and folded at least one;
at least one chip mounted on an inner surface of the facing surfaces of the folded flexible board; and
an adhesive made of an insulating material filled between the facing surfaces of said folded flexible board for sealing said chip and integratedly fixing said facing surfaces and said chip.

2. An electronic device as set forth in claim 1, wherein the chip is mounted on flat regions of said flexible board.

3. An electronic device as set forth in claim 1, wherein the flexible board is alternatively folded to form at least three stacked layers to aligne the both fold ends.

4. An electronic device as set forth in claim 1, wherein at least one chip is mounted on each surface of the facing surfaces of said folded flexible board and said adhesive is interposed between the chips.

5. An electronic device as set forth in claim 1, wherein the flexible board is connected to a base board designed for mounting the flexible board and provided with connection lands for electrically connecting said chip to a circuit formed on the base board.

6. An electronic device as set forth in claim 5, wherein the connection lands are arranged in a grid.

7. An electronic device as set forth in claim 1, wherein the chip is mounted on said flexible board by flip-chip bonding.

8. An electronic device as set forth in claim 1, wherein the chip is mounted in bare chip on said flexible board.

9. An electronic device as set forth in claim 1, wherein chips are mounted on the two surfaces of the flexible board.

10. An electronic apparatus comprising:
an electronic device having a flexible board to be folded, at least one chip mounted on a surface of said flexible board, and an adhesive made of an insulating material filled between facing surfaces of said folded board to affix the facing surfaces each other and seal said chip and
a base board on which said electronic device is to be mounted.

11. An electronic apparatus as set forth in claim 10, wherein said flexible board is connected to said base board and further comprising connection lands for electrically connecting said chip to a circuit formed on the base board.

12. A method of producing an electronic device comprising the steps of:
mounting at least one chip on a surface of a flexible board;
coating an adhesive made of an insulating material on said flexible board; and
folding said flexible board to bond with said adhesive the facing surfaces of the flexible board and seal said chip with said adhesive.

13. A method of producing an electronic device as set forth in claim 12, further comprising a step of coating said adhesive so as to cover said chip mounted on said flexible board.

14. A method of producing an electronic device as set forth in claim 12, further comprising the steps of:
mounting first and second chips at regions facing each other when said flexible board is folded;
coating said adhesive so as to cover one of said first and second chips; and
folding the flexible board to be fixed each other and seal said first and second chips with said adhesive.

15. A method of producing an electronic device as set forth in claim 12, further comprising a step of mounting a plurality of chips on the two surfaces of the flexible board.

16. A method of producing an electronic device as set forth in claim 12, further comprising a step of mounting said chips by flip-chip bonding.

17. A method of producing an electronic apparatus comprising the steps of:
mounting at least one chip on a surface of a flexible board having flexibility;
coating an adhesive made of an insulating material on said flexible board;
folding said flexible board to bond with said adhesive the facing surfaces of the flexible board and seal said chip with said adhesive; and
mounting said folded flexible board on a base board.
